(19) United States
(12) Patent Application Publication
(10) Pub. No.: US 2007/0187714 A1
(43) Pub. Date: Aug. 16, 2007

(54) OLED lighting apparatus and method

(75) Inventor: Ronald S. Cok, Rochester, NY (US)

Correspondence Address: Pamela R. Crocker;Patent Legal Staff, Eastman Kodak Company, 343 State Street, Rochester, NY, 14650-2201, US

(73) Assignee: Eastman Kodak Company

(21) Appl. No.: 11/354,517

(22) Filed: Feb. 15, 2006

(51) Int. Cl. H01L 31/111

(52) U.S. Cl. 257/114

(57) ABSTRACT

The disclosure relates to organic light emitting diode devices for area illumination. The devices include an organic light emitting diode lamp responsive to electrical power for emitting light. A controller regulates the light output from the organic light emitting diode lamp using a range selection switch for varying a power range, and a power switch responsive to the range selection switch to provide power to organic light emitting diode.

### FIELD OF THE INVENTION

The present invention relates to light emitting diodes, and more particularly to the use of organic light emitting diodes for area illumination.

### BACKGROUND OF THE INVENTION

Solid-state lighting devices made of organic light emitting diodes (OLEDs) are increasingly useful for applications requiring robustness and long life. For example, U.S. Pat. No. 6,819,036 entitled “OLED Lighting Apparatus” by Cok issued Nov. 16, 2004 describes a light apparatus including a solid-state OLED lamp having exposed electrodes and a socket for removably receiving the OLED and providing electrical connections to the electrodes to provide power to the lamp.

Organic light emitting diodes (OLEDs) can be manufactured by depositing materials on a substrate and encapsulating them with a cover or layer. This process enables the creation of single, monolithic lighting elements on a single substrate. FIG. 2 illustrates a typical prior-art construction of an OLED device on a substrate 102. A first electrode 104 is formed on the substrate 102. Organic materials 106 are deposited thereon. A second electrode 108 is formed over the organic materials 106. Both electrodes 104 and 108 extend beyond an encapsulating cover 110 and are connected to a power supply 112. When power is provided, current flows between the electrodes 104 and 108 through the organic layers 106 to emit light.

However, it is well known that OLED materials age with usage and become less efficient at emitting light for a given amount of power. Complex power control methods for detecting the change in OLED device efficiency and compensating for the consequent reduction in light emission from the OLED is described in co-pending, commonly assigned U.S. Ser. No. 11/107,163 filed Apr. 15, 2005. However, such control methods require sophisticated and expensive electronics.

### SUMMARY OF THE INVENTION

In general terms, the present invention relates to an OLED lighting apparatus having a controller for controlling the output of light from the OLED lamp for area illumination.

In one embodiment, an OLED lighting apparatus includes an OLED lamp responsive to electrical power for emitting light, and a controller for controlling the light output from the OLED lamp, the controller including a user-operated range selection switch for varying a power range, and a power switch responsive to the user-operated range selection switch to provide power to OLED.

In another embodiment, a method of operating an OLED lighting apparatus includes providing an OLED lamp responsive to electrical power for emitting light; controlling the light output from the OLED lamp by a controller, the controller providing a power switch for providing electrical power to the OLED lamp responsive to a separate user-operated range selection switch for selecting two-or-more power ranges, setting the range selection switch to a first range and operating the power switch to provide power to the OLED lamp and causing the OLED lamp to emit light, and setting the range selection switch to a second range having greater power than the first range and operating the power switch to provide greater power to the OLED lamp and causing the OLED lamp to emit light.

### BRIEF DESCRIPTION OF THE DRAWINGS

The invention may be more completely understood by considering the detailed description of various embodiments of the invention, which follows in connection with the accompanying drawings. Referring now to the drawings in which like reference numbers represent corresponding parts throughout:

FIG. 1 is a schematic diagram of one embodiment of the present invention;

FIG. 2 illustrates a prior-art cross sectional view of an OLED lamp structure;

FIGS. 3a-3c illustrate various configurations of a switch mechanism including the power switch and the range selection switch;

FIG. 4 represents another embodiment of the switch mechanism in which the range selection switch is a rotary switch having variable settings;

FIG. 5 is an embodiment of a switch mechanism having continuously variable range selection switch; and

FIG. 6 is another embodiment of a continuously variable range selection switch.

It will be understood that the figures are not to scale since the individual layers are too thin and the thickness differences of various layers too great to permit depiction to scale.

### DETAILED DESCRIPTION OF THE INVENTION

Various embodiments will be described in detail with reference to the drawings, wherein like reference numerals represent like parts and assemblies throughout the several views. Reference to various embodiments does not limit the scope of the invention, which is limited only by the scope of the claims attached hereto. Additionally, any examples set forth in this specification are not intended to be limiting and merely set forth some of the many possible embodiments for the claimed invention.

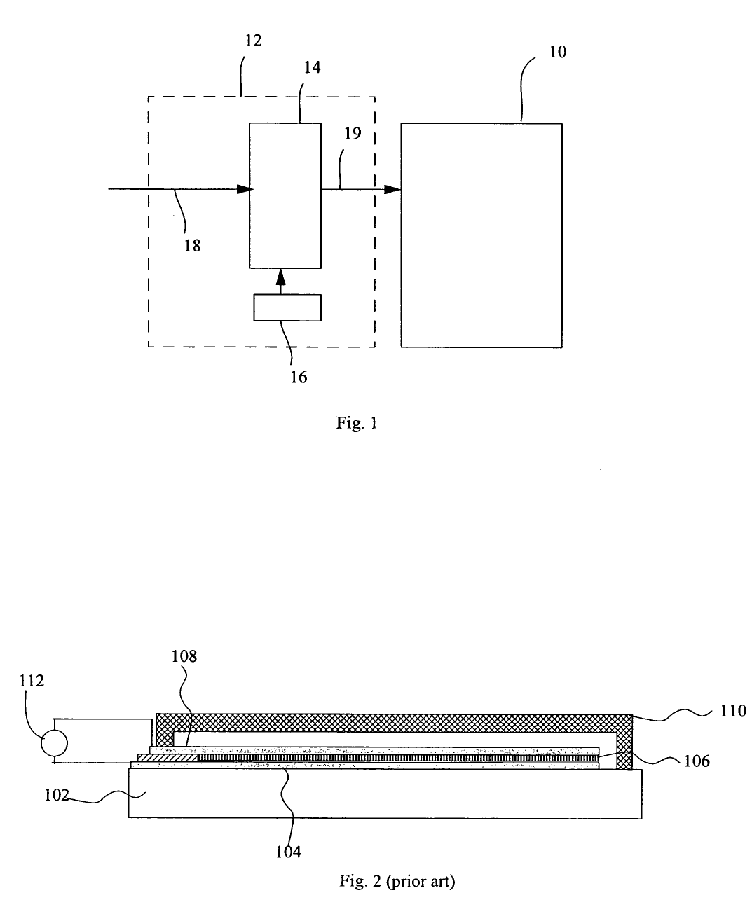

FIG. 1 is a schematic diagram of an OLED lighting device. The device has the advantage of providing an inexpensive apparatus and method for an OLED lighting apparatus having a simple, low-cost construction that compensates for OLED aging. The schematic diagram includes an organic light emitting diode (OLED) lamp 10 responsive to electrical power for emitting light and a control 12 for controlling the light output from the OLED lamp 10. The control 12 includes a power switch 14 to provide electrical power to the OLED lamp 10 and is responsive to a separate user-operated range selection switch 16 for selecting two or more power ranges. However, the range selection switch 16 is not limited to being user-operated and can be operable by any suitable technique, such as a mechanical, electro-mechanical or software device. Power for the OLED lighting apparatus can be provided by an electrical connection 18 coupled, for example, to a conventional household or commercial power grid. Power output from the control 12 can be similarly provided to the OLED lamp 10 through an electrical connection 19.

According to various embodiments, power can be provided to the OLED lamp 10 in a variety of forms, for example, by a variable alternating current and pulse width modulation of a voltage signal. By varying the current and voltage characteristics used to drive the OLED lamp 10 over time, the OLED lamp 10 can be driven at different light output levels.

The power switch 14 found in the control 12 can be, but is not limited to, a conventional on/off switch as is typically found in wall switches for incandescent or fluorescent lamps. Alternatively, power switch 14 can be a dimmer switch, a variably resistive switch, a power transistor controlled by an external signal, a switch controlled by a relay or the like. However, the power transmitted through the power switch 14 is determined by the range selection switch 16. The setting of the range selection switch 16 will determine the amount of power available to the power switch 14. For example, in a simple case, the power switch is a conventional on/off switch. If the range selection switch 16 is set to a first range setting, the power switch 14 can transmit power at a level of zero volts or a level of 60 volts ac so that the range is 60 volts. If the range selection switch 16 is set to a second range setting, the power switch 14 can transmit power at a level of zero volts or a level of 120 volts ac so that the range is 120 volts. In a more complex case, for example, the power switch 12 can have a variety of discretely variable settings, for example four settings, so that if the range selection switch 16 is set to the second range setting, the power switch 14 can transmit power at a level of zero volts, 40 volts, 80 volts, or 120 volts, but the maximum range remains 120 volts. In the extreme case, the power switch can be a continuously variable dimmer switch so that an infinite number of output power levels can be transmitted by the power switch 14 within a range selected by the range selection switch 16.

In another embodiment, the range selection switch 16 included in the control 12 can also have a variety of settings, for example two or three different settings, or can also be variable.

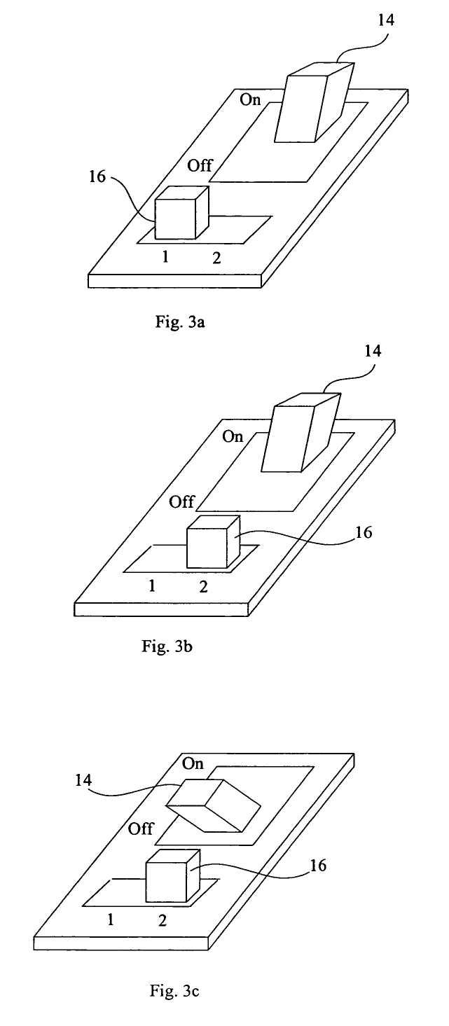

FIGS. 3a-3c illustrate various configurations for a switch mechanism including the power switch 14 and the range selection switch 16. Referring to FIG. 3a, the range selection switch 16 is set at a first range setting while the power switch 14 is set to the “on” position. In this embodiment, for example, the power switch 14 can transmit power at 60 volts ac. FIG. 3b illustrates another embodiment of the range selection switch 16 in which the range selection switch is set at a second range setting while the power switch 14 is set to the “on” position. In this embodiment, for example, the power switch 14 can transmit power at 120 volts ac. FIG. 3c is yet another embodiment of the range selection switch 16 set at a second range setting while the power switch 14 is set to the “off” position. In this embodiment, for example, the power switch 14 is not transmitting power.

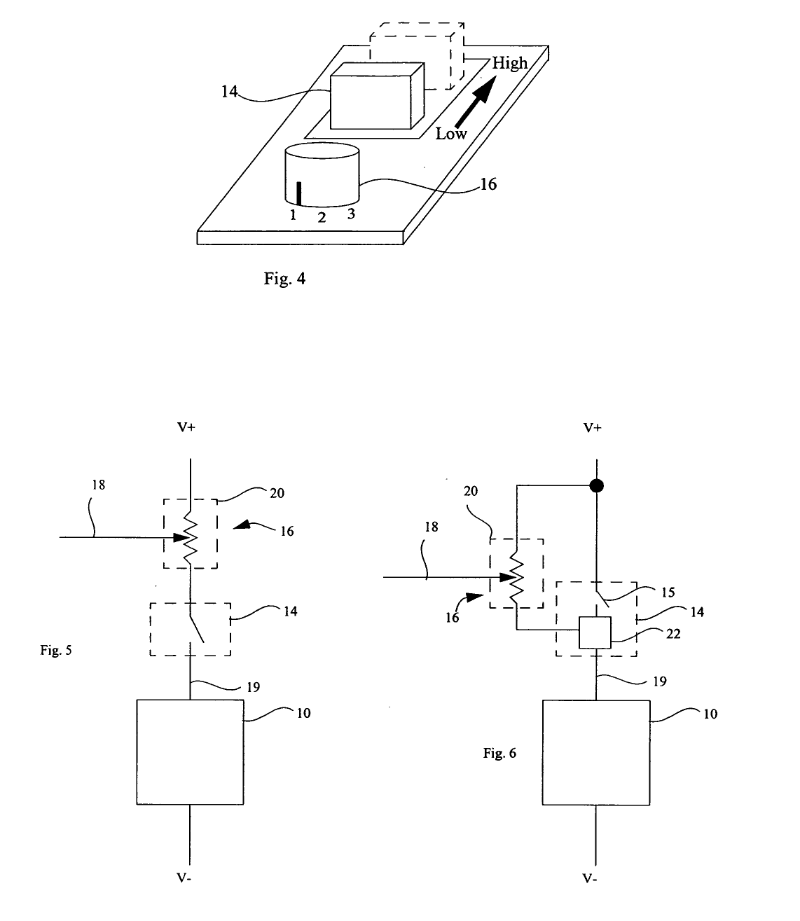

FIG. 4 represents an alternative embodiment of the switch mechanism in which the range selection switch 16 is a rotary switch having variable settings.

In one embodiment, the range selection switch 16 has three range settings and the power switch 14 is a variable switch initially set at a low position and can be continuously moved to a high position (i.e., high position is shown with dashed lines).

In operation, the range selection switch 16 will initially be set at a first low range setting so that the range of power available through the power switch 14 is also low. As the power switch 14 is turned on and the OLED lamp 10 is used, over time the light output from the OLED lamp 10 will diminish due to the aging of the OLED materials in the lamp 10. At some point, a user can find the light output of the OLED lamp 10 is unacceptably low and will set the range selection switch 16 to a second higher range setting so that the range of power available through the power switch 14 is higher than before. As the power switch 14 is turned on at the second higher range setting and the OLED lamp 10 is used, the light output from the OLED lamp 10 will be increased. Hence, the present invention improves the useful life of an OLED lamp.

The power switch 14 and the range selection switch 16 can be provided in a common housing, as shown in FIGS. 3 and 4. Alternatively, they can be provided in separate housings. The switches can be located on a wall or in a lamp fixture such as that taught in U.S. Pat. No. 6,819,036 cited above which is hereby included by reference. In one embodiment, a switch fixture can be mounted on a surface separate from the OLED lamp for providing power to the OLED lamp and the power switch 14 and/or the range selection switch 16 can be provided in the switch fixture. The range selection switch 16 can also be hidden within a fixture or housing when the range selection switch 16 is not used frequently.

Various means for providing variable power control with different ranges can be provided. Range selection switch 16 can be, for example, a power transistor controlled by an external signal or it can be a switch controlled by a relay. Co-pending, commonly assigned U.S. Ser. No. 11/107,163 filed Apr. 15, 2005 referenced above and hereby included by reference describes means of adjusting voltage levels or temporal control employing pulse width modulation. For example, FIG. 5 is an embodiment of a switch mechanism having a continuously variable range selection switch. In the embodiment of FIG. 5, the range selection switch 16 is a continuously variable range selection switch that includes a variably resistive switch 20. The range selection switch 16 is connected in series with a power switch 14, for example a mechanical switch, to provide power through electrical connection 19 to the OLED lamp 10.

FIG. 6 is another embodiment of a continuously variable range selection switch. In FIG. 6, the range selection switch 16 is a continuously variable range selection switch that includes a variably resistive switch 20. The range selection switch 16 is connected to a power switch 14 that includes a pulse-width modulation circuit 22 and a serially-connected switch 15 to provide power through electrical connection 19 to the OLED lamp 10. A voltage-controlled oscillator (not shown) can be employed to control the pulse widths of the modulation circuit as taught, for example, in the above references.

The OLEDs described above can be employed in a wide variety of conventional applications, for example in a tabletop lamp, floor lamp, chandelier, under-counter lamp, or ceiling light. The present invention can also be employed in portable illumination devices using DC power sources. A user can operate switches 14 and 16 directly or remotely. Alternatively, switching control can be provided by a computer and/or remotely controlled over a communication network, including a telephone network, video network, or the Internet. Either switch 14 or 16 can be variably controlled between two or more discrete power levels or either switch can be variably controlled at continuously variable levels.

The various embodiments described above are provided by way of illustration only and should not be construed to limit the invention. For example, in a one embodiment, the OLED layer includes Organic Light Emitting Diodes (OLEDs) which are composed of small molecule or polymeric OLEDs as disclosed in but not limited to U.S. Pat. No. 4,769,292, issued Sep. 6, 1988 to Tang et al., and U.S. Pat. No. 5,061,569, issued Oct. 29, 1991 to VanSlyke et al. Those skilled in the art will readily recognize various modifications and changes that may be made to the present invention without following the example embodiments and applications illustrated and described herein, and without departing from the true spirit and scope of the present invention, which is set forth in the following claims.

### PARTS LIST

10 OLED lamp
12 control
14 power switch
15 switch
16 range selection switch
18 electrical connection
19 electrical connection
20 continuously variable resistive switch
22 pulse-width modulation circuit
102 substrate
104 first electrode
106 organic materials
108 second electrode
110 cover
112 power supply

What is claimed is:

1. An OLED lighting apparatus, comprising:
an OLED lamp responsive to electrical power for emitting light; and
a controller for regulating the light output from the OLED lamp, the controller comprising:
a user-operated range selection switch for varying a power range; and
a power switch responsive to the user-operated range selection switch to provide power to OLED.

2. The OLED lighting apparatus of claim 1 wherein the power switch has two or more discrete power settings determined by the range selection switch.

3. The OLED lighting apparatus of claim 1 wherein the power switch has a continuously variable range of power settings determined by the range selection switch.

4. The OLED lighting apparatus of claim 1 wherein the power switch is a dimmer switch whose power range is determined by the range selection switch.

5. The OLED lighting apparatus of claim 1 wherein the range selection switch has two or more discrete settings that determine the range of power provided to the power switch.

6. The OLED lighting apparatus of claim 1 wherein the range selection switch has a continuously variable range of settings that determine the range of power provided to the power switch.

7. The OLED lighting apparatus of claim 1 wherein the power provided to the OLED lamp is selected in response to reduced output from the OLED lamp at a given power level.

8. The OLED lighting apparatus of claim 1 wherein the power switch and/or the range selection switch is a slider switch or a rotary switch.

9. The OLED lighting apparatus of claim 1 wherein the power switch and the range selection switch are provided in a common housing.

10. The OLED lighting apparatus of claim 1 wherein the power switch and the range selection switch are provided in separate housings.

11. The OLED lighting apparatus of claim 1 further comprising a lamp fixture for supporting the OLED lamp and providing power to the OLED lamp and wherein the power switch and/or the range selection switch are provided in the lamp fixture.

12. The OLED lighting apparatus of claim 1 further comprising a switch fixture mounted on a surface separate from the OLED lamp for providing power to the OLED lamp and wherein the power switch and/or the range selection switch are provided in the switch fixture.

13. The OLED lighting apparatus of claim 1 wherein the range selection switch is hidden within a lamp fixture or a switch fixture.

14. A method of operating an OLED lighting apparatus comprising:
providing an OLED lamp responsive to electrical power for emitting light;
controlling the light output from the OLED lamp by a controller, the controller providing a power switch for providing electrical power to the OLED lamp responsive to a separate user-operated range selection switch for selecting two-or-more power ranges;
setting the range selection switch to a first range and operating the power switch to provide power to the OLED lamp and causing the OLED lamp to emit light; and
setting the range selection switch to a second range having greater power than the first range and operating the power switch to provide greater power to the OLED lamp and causing the OLED lamp to emit light.
